(19) United States
(12) Patent Application Publication
(10) Pub. No.: US 2025/0105177 A1
(43) Pub. Date: Mar. 27, 2025

(54) SEMICONDUCTOR DEVICE

(71) Applicant: KABUSHIKI KAISHA TOSHIBA, Tokyo (JP)

(72) Inventors: Shogo MINAMI, Ota Tokyo (JP); Keiichiro MATSUO, Yokohama Kanagawa (JP); Tetsuya YAMAMOTO, Sagamihara Kangawa (JP)

(21) Appl. No.: 18/604,297

(22) Filed: Mar. 13, 2024

(30) Foreign Application Priority Data
Sep. 22, 2023 (JP) 2023-158111

(51) Int. Cl. H01L 23/00; H01L 23/31

(52) U.S. Cl. CPC H01L 24/05; H01L 23/293; H01L 24/48; H01L 2224/02165; H01L 2224/0384; H01L 2224/04042; H01L 2224/05551; H01L 2224/48472; H01L 2224/48992; H01L 2224/85205; H01L 2224/85855

(57) ABSTRACT

A semiconductor device 100 according to an embodiment including: a semiconductor element 2 placed on an insulating substrate 1 and having an electrode 21 on a surface 2a; a bonding wire 3 bonded to the electrode 21 and electrically coupling the semiconductor element 2; and a first resin material 4 covering a bonding portion 31 between the electrode 21 and the bonding wire 3, the bonding portion 31 includes a non-bonding region 32 where the electrode 21 and the bonding wire 3 are not bonded.

### CROSS-REFERENCE TO RELATED APPLICATIONS

This application is based upon and claims the benefit of priority from Japanese Patent Application No. 2023-158111, filed on Sep. 22, 2023; the entire contents of which are incorporated herein by reference.

### FIELD

An embodiment relates to a semiconductor device.

### BACKGROUND

There has been developed a semiconductor device including an insulating substrate having a conductor pattern, a semiconductor element having a surface on which an electrode is provided and a back surface bonded to the conductor pattern, and a bonding wire bonded to the electrode. In such a semiconductor device, there is room for improvement from the viewpoint of durability, as breakage occurs at a bonding portion between the electrode and the bonding wire after repeated use.

### DESCRIPTION OF THE DRAWINGS

FIG. 1 is a cross-sectional view of main parts of a semiconductor device 100 according to an embodiment.

FIG. 2 is an enlarged cross-sectional view of the semiconductor device 100.

FIG. 3 is an enlarged plan view of the semiconductor device 100.

FIGS. 4A to 4C are diagrams showing a method for manufacturing the semiconductor device 100.

FIG. 5 is a diagram of a semiconductor device R according to a reference example, which corresponds to FIG. 2.

FIG. 6 is a diagram of the semiconductor device 100 according to Variation 1, which corresponds to FIG. 3.

FIG. 7 is a diagram of the semiconductor device 100 according to Variation 2, which corresponds to FIG. 2.

FIG. 8 is a diagram of the semiconductor device 100 according to Variation 3, which corresponds to FIG. 2.

FIG. 9 is a diagram showing an analysis result of creep analysis.

FIGS. 10A and 10B are diagrams showing the analysis result of the creep analysis.

FIG. 11 is a diagram showing an analysis model for estimating a width of an inelastic region.

FIG. 12 is a diagram showing an analysis result for estimating the width of the inelastic region.

FIGS. 13A and 13B are diagrams showing the analysis result for estimating the width of the inelastic region.

FIG. 14 is a diagram showing the analysis result for estimating the width of the inelastic region.

### DETAILED DESCRIPTION

A semiconductor device according to an embodiment including: a semiconductor element placed on an insulating substrate and having an electrode on a surface; a bonding wire bonded to the electrode and electrically coupling the semiconductor element; and a first resin material covering a bonding portion between the electrode and the bonding wire, the bonding portion includes a non-bonding region where the electrode and the bonding wire are not bonded.

### 1. Embodiment

### (1.1. Semiconductor Device 100)

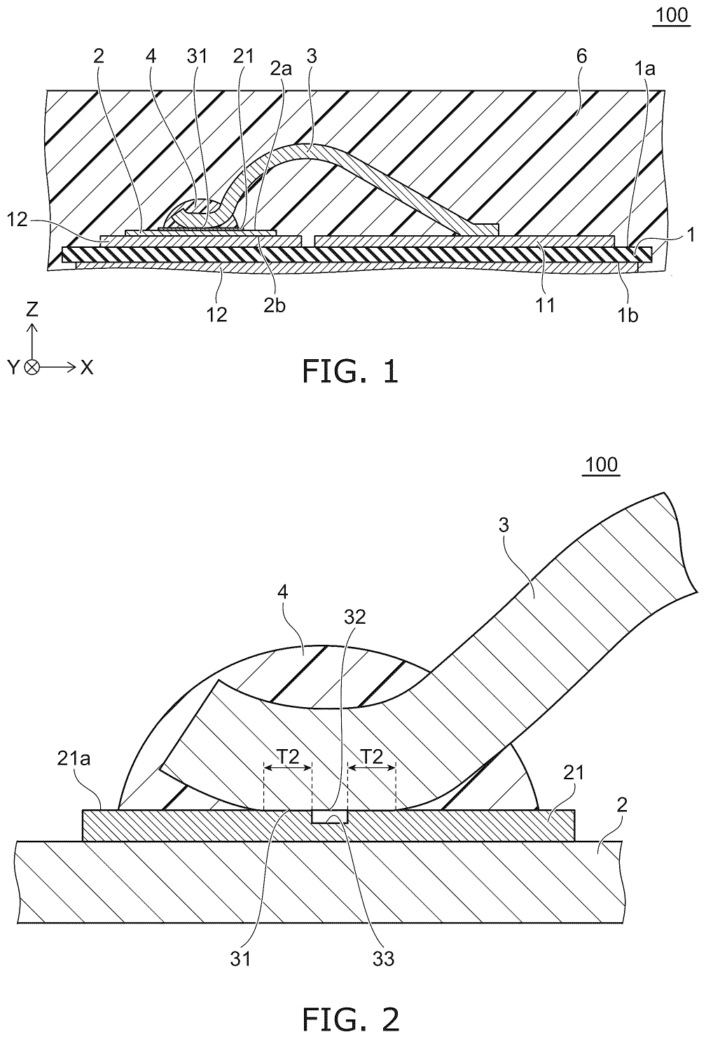

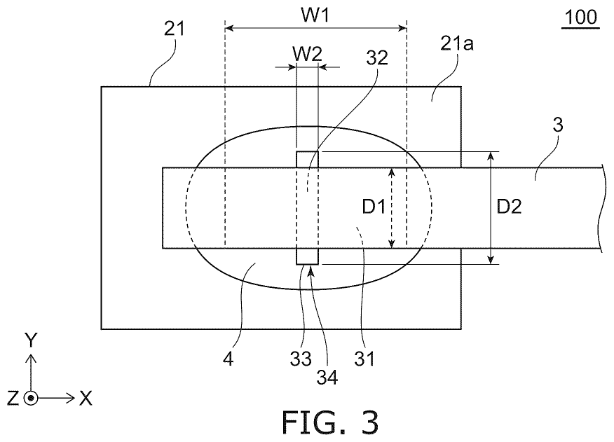

Hereinafter, an embodiment will be described. In the drawings shown below, directions may be shown by an X-axis, a Y-axis, and a Z-axis shown in FIGS. 1 and 3. Specifically, an X-axis direction along the X-axis shows an extending direction of a bonding wire 3 in FIG. 1. A Y-axis direction along the Y-axis shows a direction orthogonal to the X-axis direction on a horizontal plane. A Z-axis direction along the Z-axis shows a vertical direction. A positive direction on the Z-axis is upward, and a negative direction on the Z-axis is downward.

FIG. 1 is a cross-sectional view of main parts of the semiconductor device according to the embodiment. As shown in FIG. 1, the semiconductor device 100 mainly includes an insulating substrate 1, a semiconductor element 2, and the bonding wire 3. The semiconductor device 100 may further include a base plate on which the insulating substrate 1 is placed, a case that accommodates the insulating substrate 1, the semiconductor element 2, and the bonding wire 3, and a heat sink for dissipating heat from the semiconductor element 2.

The insulating substrate 1 has a surface 1a and a back surface 1b. The back surface 1b is a face opposite to the surface 1a. For example, alumina (Al₂O₃) or aluminum nitride (AlN) is used for the insulating substrate 1.

A conductor pattern 12 is provided on the insulating substrate 1. For example, copper (Cu) is used for the conductor pattern 12.

The semiconductor element 2 has a surface 2a and a back surface 2b. The back surface 2b is a face opposite to the surface 2a. As an example, the semiconductor element 2 may be a power semiconductor element having a vertical structure in which a current flows from the surface 2a toward the back surface 2b. The semiconductor element 2 may be a switching element such as an insulated gate bipolar transistor (IGBT) or a vertical metal oxide semiconductor field effect transistor (MOSFET), or a rectifying element such as a Schottky barrier diode.

As an example, the semiconductor element 2 is formed using a single crystal of silicon (Si). However, a semiconductor material constituting the semiconductor element 2 is not limited thereto. As another example, the semiconductor element 2 may be formed using a semiconductor material having a wide band gap such as silicon carbide (SIC) or silicon nitride (GaN).

An electrode 21 is provided on the surface 2a of the semiconductor element 2. The electrode 21 is made of, for example, an Al alloy containing Al or Si. The electrode 21 may further include a coating layer. For the coating layer, for example, Ni, Au, or a structure in which these elements are stacked may be used.

The bonding wire 3 is a metal wire that electrically couples the semiconductor element 2 and a lead frame 11. For example, Au, Al, or Cu is used for the bonding wire 3. The electrode 21 has a bonding portion 31 to be bonded to the bonding wire 3. As an example, the bonding portion 31 is formed into a rectangular shape in a plan view by ultrasonic bonding.

At the bonding portion 31, the bonding wire 3 and the electrode 21 are bonded along the extending direction of the bonding wire 3 (hereinafter, also simply referred to as an extending direction). The bonding portion 31 includes a non-bonding region 32 where the electrode 21 and the bonding wire 3 are not bonded. In the example shown in FIGS. 2 and 3, the non-bonding region 32 is formed by providing a recess 33 in an upper surface 21a of the electrode 21.

Specifically, as shown in FIG. 2, the recess 33 is formed in a groove shape having a rectangular cross section and extending in the Y-axis direction, and is provided in a central portion of the bonding portion 31 in the extending direction. Further, as shown in FIG. 3, the recess 33 is formed in a rectangular shape in a plan view. In this way, the non-bonding region 32 is formed in the bonding portion 31 by an opening 34 of the recess 33 on the upper surface 21a.

A ratio of a length W2 of the recess 33 to a length W1 of the bonding portion 31 in the X-axis direction (that is, the extending direction of the bonding wire 3) is preferably 6% or more, and more preferably 10% or more. A length D2 of the recess 33 is favorably longer than a length D1 of the bonding portion 31 in the Y-axis direction. In this way, a region not covered with the bonding wire 3 occurs in the opening 34, and a first resin material 4 can be easily filled into the recess 33.

The bonding portion 31 is covered with the first resin material 4. In the example shown in FIGS. 1 to 3, the bonding wire 3 around the bonding portion 31 is covered with the first resin material 4. However, the first resin material 4 does not need to cover the entire bonding wire 3 around the bonding portion 31. As an example, the first resin material 4 may cover a gap between the bonding wire 3 and the electrode 21 at both ends of the bonding portion 31 in the extending direction without covering the bonding wire 3 above the bonding portion 31.

The first resin material 4 functions as a reinforcing material for reinforcing the bonding in the bonding portion 31. A Young's modulus of the first resin material 4 is favorably 1000 MPa or more. Examples of the material to be used for the first resin material 4 include polyimide.

As shown in FIG. 1, a second resin material 6 is filled in a case of the semiconductor device 100. Accordingly, the second resin material 6 seals the insulating substrate 1, the semiconductor element 2, and the bonding wire 3. The second resin material 6 has insulating properties. It is favorable that the second resin material 6 has a Young's modulus lower than that of the first resin material 4. Accordingly, it is possible to prevent the second resin material 6 from being peeled off from the surface of the semiconductor element 2 due to a difference in a thermal expansion coefficient from the semiconductor element 2. More specifically, an elastic modulus of the second resin material 6 is favorably 0.1 MPa or less. Examples of the material to be used for the second resin material 6 include silicone gel.

### (1.2. Method for Manufacturing Semiconductor Device 100)

Hereinafter, a manufacturing process of the semiconductor device 100 according to the embodiment will be described. The manufacturing process of the semiconductor device 100 includes a recess forming process, a bonding process, a covering process, and a sealing process.

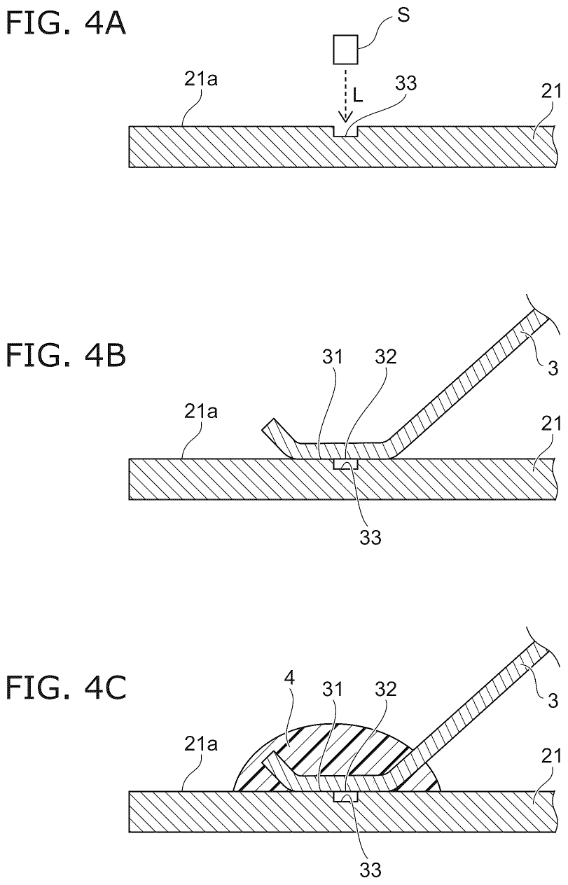

First, the recess forming process is performed. As shown in FIG. 4A, in the recess forming process, the recess 33 is formed. The recess 33 is formed by, for example, irradiating the electrode 21 with a laser light L from a laser light irradiation source S. The laser light L is emitted to a portion to which the bonding wire 3 is bonded and which becomes the bonding portion 31. The laser light irradiation source S is, for example, a carbon dioxide laser processing machine.

Next, as shown in FIG. 4B, in the bonding process, the bonding wire 3 is bonded to the electrode 21 of the semiconductor element 2. For example, the bonding wire 3 containing Al and the electrode 21 containing an Al alloy containing Si are bonded at the bonding portion 31 of the electrode 21 by ultrasonic bonding.

Next, as shown in FIG. 4C, in the covering process, the liquid first resin material 4 is supplied to the bonding portion 31. As an example, when the first resin material 4 is a resin, a mixture of a main agent and a curing agent may be dropped in the vicinity of the bonding portion 31.

In the covering process, the supplied liquid first resin material 4 is cured. As an example, when the first resin material 4 is a resin, the first resin material 4 is cured by holding the liquid first resin material 4 at a room temperature. As another example, when the first resin material 4 is a solder alloy, the first resin material 4 is cured by cooling the liquid first resin material 4. Accordingly, the bonding portion 31 is covered with the first resin material 4.

Next, in the sealing process, the semiconductor element 2, the bonding wire 3, and the first resin material 4 are accommodated in the case of the semiconductor device 100. Further, the liquid second resin material 6 is supplied into the case. By curing the liquid second resin material 6, as shown in FIG. 1, the insulating substrate 1, the semiconductor element 2, and the bonding wire 3 are sealed by the second resin material 6.

### (1.3. Summary)

According to the embodiment described above, the semiconductor device 100 includes the semiconductor element 2 placed on the insulating substrate 1 and having the electrode 21 on the surface 2a, the bonding wire 3 bonded to the electrode 21 and electrically coupling the semiconductor element 2, and the first resin material 4 covering the bonding portion 31 between the electrode 21 and the bonding wire 3. The bonding portion 31 includes the non-bonding region 32 where the electrode 21 and the bonding wire 3 are not bonded. With such a configuration, when electricity is repeatedly applied to the bonding wire 3, it is possible to reduce a thermal stress generated due to a difference in a thermal expansion coefficient between the bonding wire 3 and the electrode 21. Accordingly, it is possible to prevent occurrence of breakage in the bonding wire 3 in the vicinity of the bonding portion 31, and durability of the semiconductor device 100 is improved.

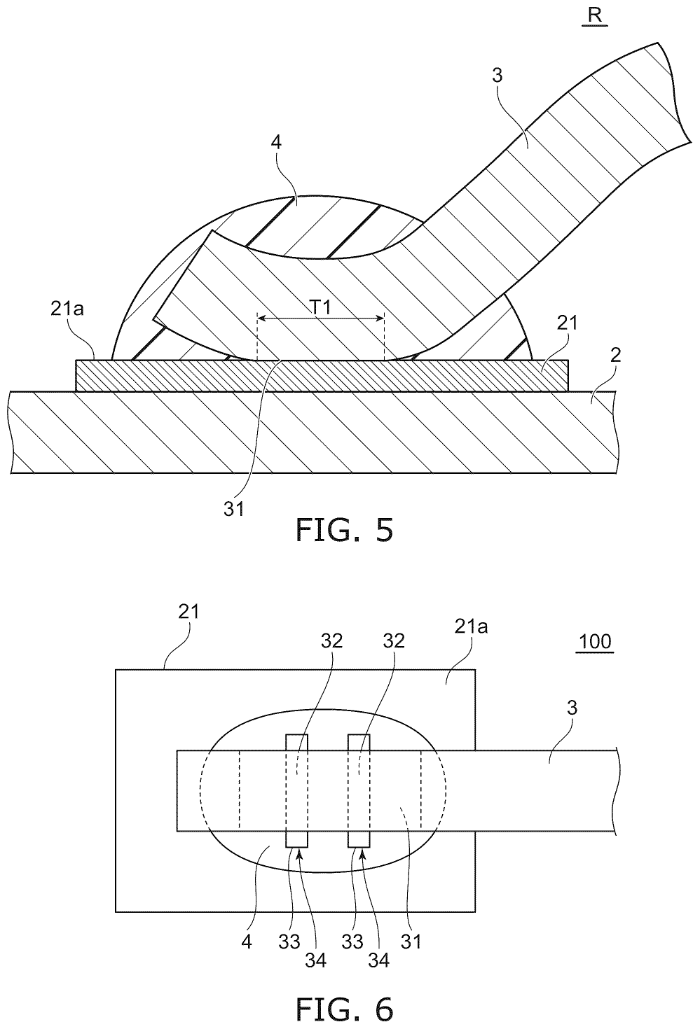

More specifically, for example, in a semiconductor device R as a reference example shown in FIG. 5, a thermal stress is generated over an interval T1 between both ends of the bonding portion 31 in the extending direction. On the other hand, as shown in FIG. 2, in the semiconductor device 100 according to the embodiment, the recess 33 is provided at a center of the bonding portion 31 in the extending direction, and the non-bonding region 32 is formed accordingly. Therefore, a region where the thermal stress may be generated is divided by the non-bonding region 32, and the thermal stress is generated at intervals T2 from an end of the bonding portion 31 to an end of the non-bonding region 32 on both sides of the recess 33. Since the interval T2 is shorter than the interval T1, a deformation amounts due to thermal expansion generated in the semiconductor device 100 is smaller than that of the semiconductor device R, and the generated thermal stress is also smaller. As described above, in the semiconductor device 100 according to the embodiment, since the bonding portion 31 includes the non-bonding region 32, it is possible to disperse the thermal stress that may be generated inside the bonding wire 3.

### (1.4. Variations)

The semiconductor device 100 according to a variation of the embodiment will be described with reference to FIGS. 6 to 8, focusing on differences from the above embodiment. FIG. 6 is an enlarged plan view of the semiconductor device 100 according to Variation 1. The Variation 1 is different from the above embodiment in that the semiconductor device 100 includes multiple recesses 33 in the upper surface 21a of the electrode 21. In the example shown in FIG. 6, two recesses 33 are provided in parallel along the extending direction on the upper surface 21a of the electrode 21. With such a configuration, it is possible to more finely disperse the thermal stress generated along with energization to the bonding wire 3 along the extending direction. The example shown in FIG. 6 is an example, and the number of the recesses 33 provided in the upper surface 21a of the electrode 21 may be three or more.

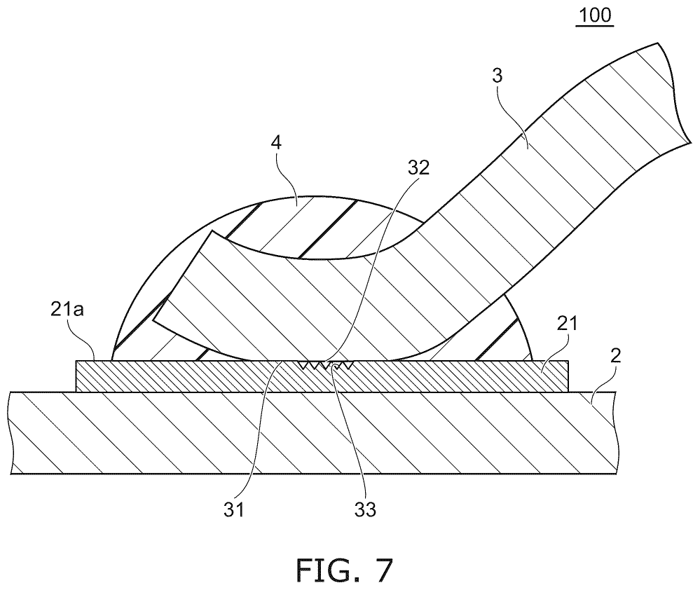

FIG. 7 is an enlarged plan view of the semiconductor device 100 according to Variation 2. In the Variation 2, a shape of the recess 33 provided in the upper surface 21a of the electrode 21 is different from that of the above-described embodiment. In the example shown in FIG. 7, the recess 33 having a bottom surface with a sawtooth cross section is formed in the upper surface 21a of the electrode 21. With such a configuration, effects same as those of the above-described embodiment can be achieved.

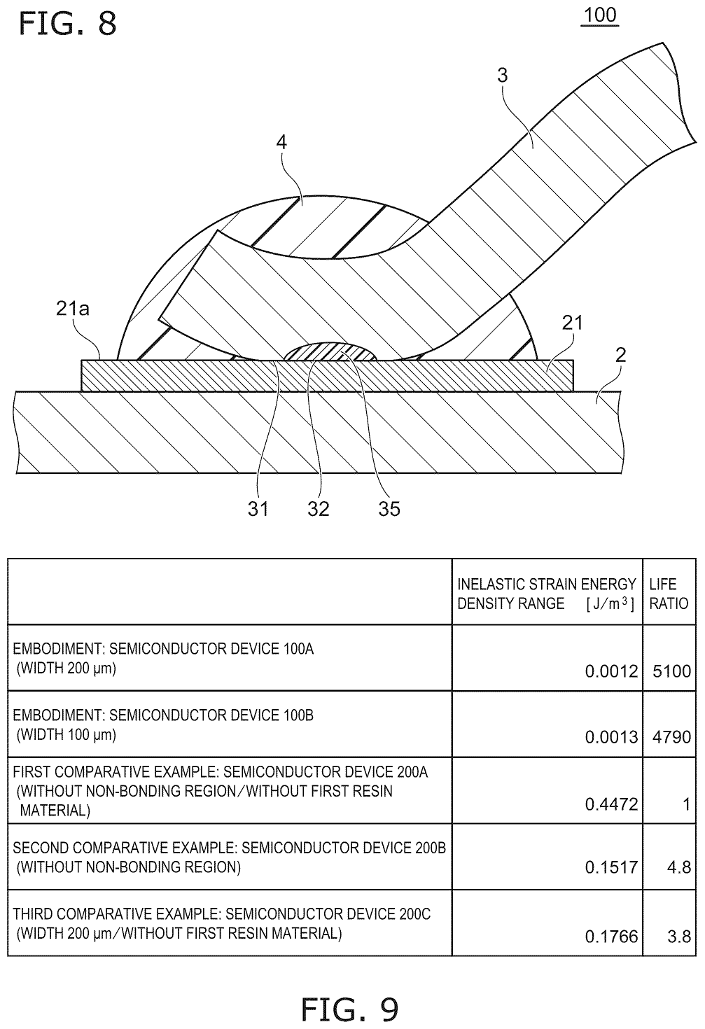

FIG. 8 is an enlarged plan view of the semiconductor device 100 according to Variation 3. The Variation 3 is different from the above-described embodiment in that a shielding layer 35 is provided instead of forming the recess 33 in the upper surface 21a of the electrode 21. In the example shown in FIG. 8, the shielding layer 35 containing a third resin material is stacked on the upper surface 21a of the electrode 21. Accordingly, the non-bonding region 32 where the electrode 21 and the bonding wire 3 cannot be ultrasonically bonded is formed in a partial region of the bonding portion 31. The third resin material may be, for example, an insulating material, and specific examples thereof include polyimide, polyimide silicone, polyamide imide, an epoxy resin, a phenol resin, and a resin containing a filler which is a conductive material. As the filler, for example, metal or ceramics can be used. By adding the filler, thermal conductivity and the electrical conductivity can be improved. The shielding layer 35 is not limited to a resin material, and may be any material that can shield the ultrasonic bonding between the electrode 21 and the bonding wire 3, such as an Ag sintered body or a solder material. With such a configuration, effects same as those of the above-described embodiment can be achieved.

### 2. Examples

Hereinafter, examples of the semiconductor device 100 according to the embodiment will be described. As the examples, creep analysis and estimation of a width of the non-bonding region will be shown below.

### (2.1. Creep Analysis)

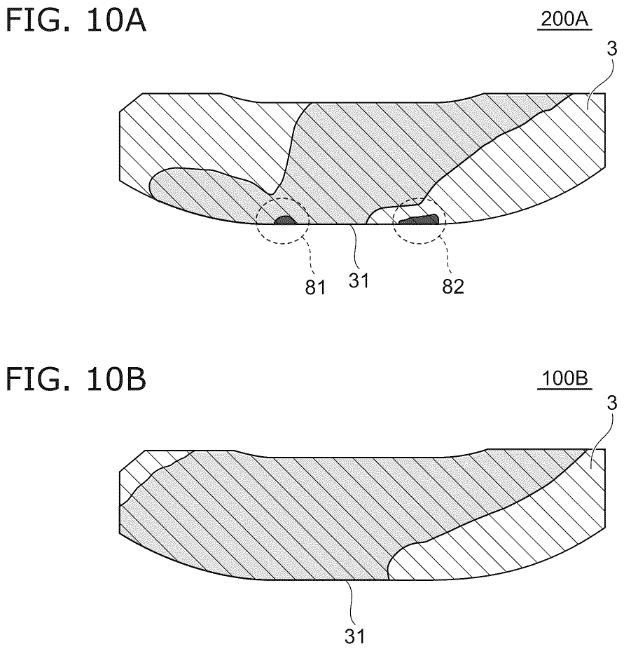

Results of the creep analysis as the example will be described with reference to FIGS. 9 and 10A and 10B.

In the creep analysis, an inelastic strain energy density range and a life ratio were calculated for two examples and three comparative examples shown below.
A semiconductor device 100A according to the embodiment (width of the non-bonding region 32:200 μm)
A semiconductor device 100B according to the embodiment (width of the non-bonding region 32:100 μm)
A semiconductor device 200A according to a first comparative example (without the non-bonding region 32/without the first resin material 4).
A semiconductor device 200B according to a second comparative example (without the non-bonding region 32).
A semiconductor device 200C according to a third comparative example (width of the non-bonding region 32:200 μm/without the first resin material 4)

As a thermal condition, a temperature change from 40° C. to 140° C. was assumed by repeatedly turning ON a current flowing to the semiconductor element 2 for 2 seconds and turning it OFF for 8 seconds. Accordingly, heat generation densities given to the semiconductor element 2 and the bonding wire 3 were 6.3 (W/mm³) for the semiconductor element 2 and 0.45 (W/mm³) for the bonding wire 3.

A mesh model was divided into mesh elements of 10 μm×10 μm. It was assumed that the mesh element of the electrode 21 and the mesh element of the bonding wire 3 were not adjacent to each other in the non-bonding region 32 of the bonding portion 31. The inelastic strain energy density range was obtained from both ends of the bonding portion 31 in the X-axis direction. The inelastic strain energy density range means inelastic strain energy generated per unit quantity.

FIG. 9 is a diagram showing calculation results obtained by the creep analysis. As shown in FIG. 9, in the semiconductor devices 100A and 100B according to the embodiment, the inelastic strain energy density range (J/m³) could be lowered by two orders of magnitude compared to the first to third comparative examples. That is, based on the example, since the semiconductor devices 100A and 100B according to the embodiment have the above-described configuration, it can be seen that energy of thermal strain generated inside the bonding wire 3 can be reduced.

In the semiconductor devices 100A and 100B according to the embodiment, a life ratio of about 5000 times that of the first comparative example was calculated. That is, based on the example, it can be seen that the semiconductor devices 100A and 100B can have high durability by reducing the energy of thermal strain generated inside the bonding wire 3.

FIGS. 10A and 10B are diagrams showing distributions of the thermal stress generated inside the bonding wire 3 in the creep analysis. In FIGS. 10A and 10B, portions where the thermal stress inside the bonding wire 3 is stronger are indicated in darker gray.

As shown in FIG. 10A, in the semiconductor device 200A according to the first comparative example, a strong stress was generated at both ends of the bonding portion 31 in the extending direction. Meanwhile, as shown in FIG. 10B, in the semiconductor device 100B according to the embodiment, no strong thermal stress was generated at both ends of the bonding portion 31 in the extending direction. That is, based on the example, it can be seen that the generation of the thermal stress due to the difference in the thermal expansion coefficient between the bonding wire 3 and the electrode 21 can be prevented in the semiconductor device 100B.

### (2.2. Estimation of Width of Non-Bonding Region 32)

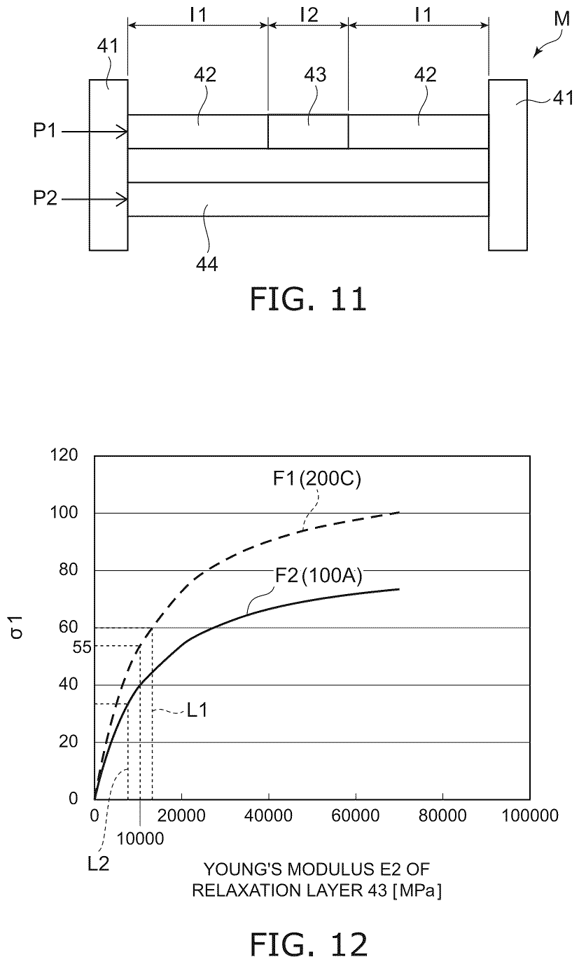

Results of estimation of the width of the non-bonding region 32 in the examples will be described with reference to FIGS. 11 to 14. FIG. 11 shows a model M corresponding to the electrode 21 in the vicinity of the bonding portion 31. The model M includes ends 41, a bonding layer 42, a relaxation layer 43, and a lower layer 44. The end 41 corresponds to the end of the bonding portion 31. The bonding layer 42 corresponds to the bonding portion 31 of the electrode 21. The relaxation layer 43 corresponds to the recess 33 provided in the electrode 21. The lower layer 44 corresponds to a layer below the recess 33 of the electrode 21.

First, in the semiconductor device 200C according to the third comparative example which does not include the first resin material 4, a change F1 of a stress σ1 generated inside the model M when a Young's modulus E2 of the relaxation layer 43 was changed was calculated. Here, a formula (3) was derived from the following conditional formulas (1) and (2), assuming that a pressure on the bonding layer 42 is P1 and a pressure on the lower layer 44 is P2.

$$P 1 + P 2 = 0 \qquad FORMULA ( 1 )$$

$$2 λ1 + λ 2 = λ3 \qquad FORMULA ( 2 )$$

$$σ1 = \frac{2 l 1 α 1 + l2 α 2 - ( 2 l 1 + l 2 ) α 3}{\frac{2 l 1}{E 1} + \frac{l 2}{E 2} + \frac{2 l 1 + l 2}{E 3}} \cdot Δ T \qquad FORMULA ( 3 )$$

I1: Length of the bonding layer 42, I2: Length of the relaxation layer 43
λ1: Elongation of the bonding layer 42, λ2: Elongation of the relaxation layer 43, λ2: Elongation of the lower layer 44
α1: Thermal expansion coefficient of the bonding layer 42, α2: Thermal expansion coefficient of the relaxation layer 43, α3: Thermal expansion coefficient of the lower layer 44

E1: Young's modulus of the bonding layer 42, E2: Young's modulus of the relaxation layer 43, E3: Young's modulus of the lower layer 44
ΔT: Temperature change

Next, in the semiconductor device 100A according to the embodiment including the first resin material 4, a change F2 of the stress σ1 generated inside the model M when the Young's modulus E2 of the relaxation layer 43 was changed was calculated. Here, a formula (5) was derived from a conditional formula (4) below.

$$2 λ 1 + λ 2 = 0 \qquad FORMULA ( 4 )$$

$$σ1 = \frac{E 1 E 2 ( α 1 l 1 + α 2 l 2 )}{2 l 1 E 2 + l 2 E 1} \cdot Δ T \qquad FORMULA ( 5 )$$

Based on the above formulas (3) and (5), the change F1 of the stress 1 in the semiconductor device 200C according to the comparative example and the change F2 of the stress σ1 in the semiconductor device 100A according to the embodiment when the Young's modulus E2 of the relaxation layer 43 was changed were obtained as shown in FIG. 12.

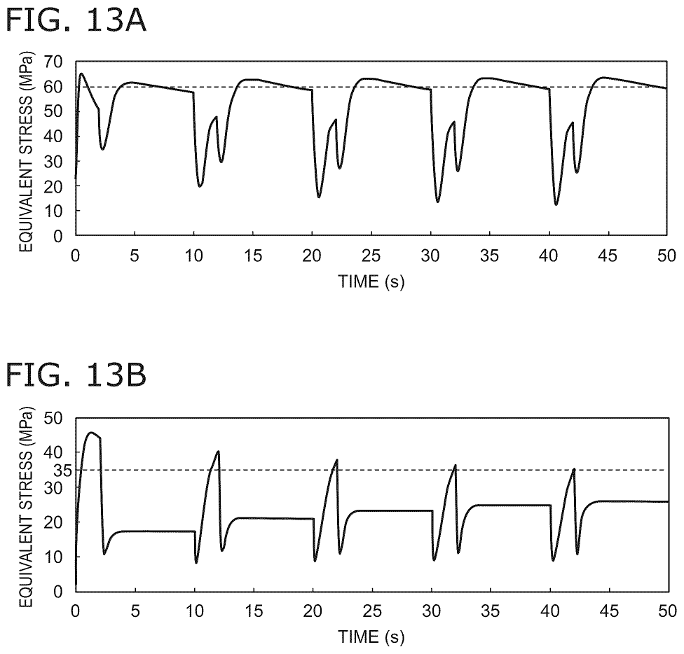

Next, in the creep analysis described above, an equivalent stress generated in the bonding portion 31 was estimated for the semiconductor device 200C according to the comparative example and the semiconductor device 100A according to the embodiment. FIG. 13A is a diagram showing a temporal change in the equivalent stress generated in the bonding portion 31 of the semiconductor device 200C according to the comparative example in the creep analysis. Based on FIG. 13A, it is seen that an equivalent stress of approximately 60 Mpa at maximum is generated while converging with time.

FIG. 13B is a diagram showing a temporal change in the equivalent stress generated in the bonding portion 31 of the semiconductor device 100A according to the embodiment in the creep analysis. Based on FIG. 13B, it is seen that an equivalent stress of approximately 35 Mpa at maximum is generated while converging with time.

FIG. 12 shows a line L1 (red line) indicating the Young's modulus E2 when the stress σ1 is 60 MPa in the semiconductor device 200C according to the comparative example, and a line L2 (blue line) indicating the Young's modulus E2 when the stress σ1 is 35 MPa in the semiconductor device 100A according to the embodiment. Here, in the creep analysis described above, since the bonding portion 31 of the semiconductor device 200C exhibits elastic-plasticity and the bonding portion 31 of the semiconductor device 100A exhibits elasticity, the Young's modulus E2 of the relaxation layer 43 was estimated to be between the line L1 and the line L2. In the analysis, the Young's modulus E2 of the relaxation layer 43 was estimated to be 10000 MPa. At this time, from a value of F2 at E2=10000 Pa in FIG. 12, it was estimated that a stress of at least 55 MPa was generated in the bonding portion 31.

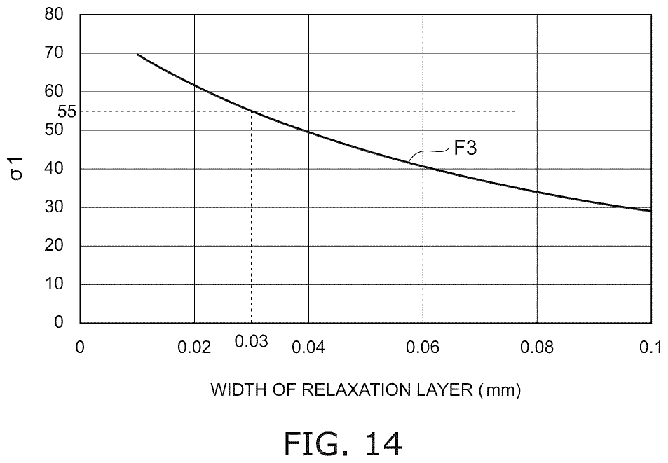

Next, based on the above-described formula (5), in the semiconductor device 100A according to the embodiment, a change F3 of the stress σ1 generated inside the model M when a length I2 of the relaxation layer 43 was changed was calculated. F3 was obtained as shown in FIG. 14. For F3 in FIG. 14, a width of the relaxation layer 43 corresponding to the stress of 55 MPa estimated above was found to be 0.03 mm (=30 μm). From this, it was determined that the length of the recess 33 corresponding to the relaxation layer 43 in the extending direction was favorably 30 μm or more. In addition, since the length of the bonding portion 31 along the extending direction of the bonding wire 3 in the analysis was 480 μm, it was estimated that a ratio of the length of the recess 33 to the length of the bonding portion 31 along the extending direction was favorably 6% or more.

### 3. Another Embodiment

The embodiment in the disclosure is described above, but the disclosure is not limited thereto. For example, in the above embodiment, although one recess 33 provided in the upper surface 21a of the electrode 21 is provided at the center of the bonding portion 31 in the extending direction, the disclosure is not limited to the embodiment, and one recess may be provided at a location other than the center in the extending direction.

In the above embodiment, the length D2 of the recess 33 is longer than the length D1 of the bonding portion 31 in the Y-axis direction, and the disclosure is not limited to the embodiment. For example, the length D2 of the recess 33 in the Y-axis direction may be the same as the length D1 of the bonding portion 31 or may be shorter than the length D1 of the bonding portion 31.

In addition, the recess 33 may have a shape other than those described above. Specifically, for example, the recess 33 may be formed by providing multiple dimple-shaped irregularities on the surface of the bonding portion 31 of the electrode 21. In other embodiments, by applying the technical idea of the disclosure, the effects same as those of the above embodiments can also be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor element placed on an insulating substrate and having an electrode on a surface;
a bonding wire bonded to the electrode and electrically coupling the semiconductor element; and
a first resin material covering a bonding portion between the electrode and the bonding wire,
the bonding portion includes a non-bonding region where the electrode and the bonding wire are not bonded.

2. The device according to claim 1, further comprising:
a second resin material sealing the semiconductor element, the bonding wire, and the first resin material,
a Young's modulus of the second resin material being lower than a Young's modulus of the first resin material.

3. The device according to claim 1, wherein
a Young's modulus of the first resin material is 1000 MPa or more.

4. The device according to claim 1, wherein
a recess is provided in an upper surface of the electrode, and
the non-bonding region is formed by an opening of the recess provided in the upper surface.

5. The device according to claim 2, wherein
a recess is provided in an upper surface of the electrode, and
the non-bonding region is formed by an opening of the recess provided in the upper surface.

6. The device according to claim 3, wherein
a recess is provided in an upper surface of the electrode, and
the non-bonding region is formed by an opening of the recess provided in the upper surface.

7. The device according to claim 4, wherein
in the bonding portion, the bonding wire and the electrode are bonded along an extending direction of the bonding wire, and
a ratio of a length of the recess to a length of the bonding portion along the extending direction is 6% or more.

8. The device according to claim 4, wherein
in the bonding portion, the bonding wire and the electrode are bonded along an extending direction of the bonding wire, and
the recess is provided at a center of the bonding portion in the extending direction.

9. The device according to claim 1, wherein
the non-bonding region has a shielding layer that is not ultrasonically bonded between the electrode and the bonding wire.
